(19) United States
(12) Patent Application Publication
(10) Pub. No.: US 2008/0182037 A1
(43) Pub. Date: Jul. 31, 2008

(54) Method of forming metal layer

(75) Inventors: Bum-seok Seo, Yongin-si (KR); Jung-hyun Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/902,842

(22) Filed: Sep. 26, 2007

(30) Foreign Application Priority Data
Jan. 31, 2007 (KR) 10-2007-0010091

(51) Int. Cl. C23C 16/06

(52) U.S. Cl. 427/576

(57) ABSTRACT

Provided is a method of forming a metal layer. The method may include supplying a first source gas into a reaction chamber containing a substrate, purging the first source gas by supplying a first purging gas into the reaction chamber, supplying a first reactive gas containing nitrogen into the reaction chamber, and purging reaction byproducts generated by the first reactive gas by supplying a second purging gas into the reaction chamber. A plasma of the first reactive gas is formed on the substrate by applying a first RF power to the substrate when the first reactive gas is supplied to form a first metal layer.

### CLAIM OF PRIORITY

A claim of priority is made to Korean Patent Application No. 10-2007-0010091, filed on Jan. 31, 2007, in the Korean Intellectual Property Office, the disclosure of which is incorporated herein in its entirety by reference.

### BACKGROUND

1. Field of the Invention

Example embodiments of the present invention may relate to a method of forming a thin layer, and more particularly, to an atomic layer deposition (ALD) method of forming a metal layer.

2. Description of the Related Art

Conductive films used in semiconductor memory devices are usually formed by a chemical vapor deposition (CVD) method or a physical vapor deposition (PVD) method in semiconductor manufacturing processes.

As the degree of integration of semiconductor devices increases, a deposition method having excellent step coverage characteristics is required. However, the CVD and the PVD methods are not likely to satisfy this requirement. An atomic layer deposition (ALD) method has been suggested as an alternative to the CVD and PVD methods. Using the ALD method, a film having a thickness of an atomic layer may be deposited. For example, a conductive film with a surface having a hole with a large aspect ratio may be formed with consistent thickness.

In particular with DRAMs, as the degree of integration increases, a height of a capacitor included therein also increases. Therefore, the ALD method may be used to form lower electrode and upper electrode portions of the capacitor.

However, the following problems may occur when the ALD is used to form metal layers such as the upper and lower electrodes of the capacitor.

First, lower electrodes may be oxidized when a metal layer is formed using the conventional ALD method (hereinafter, referred to as the conventional ALD) because the conventional ALD method uses oxygen as a reactive gas. The oxidization of the lower electrode may decrease the reliability of semiconductor memory devices. For example, when a lower electrode of a capacitor is formed using the conventional ALD method, a diffusion barrier layer formed under the lower electrode may be oxidized. Furthermore, when the diffusion barrier layer is oxidized, the volume of the diffusion barrier layer increases thereby hindering contact between the diffusion barrier layer and a conductive plug formed thereunder.

Second, it is difficult to form a pure metal layer using the conventional ALD method. The conventional ALD method uses a metal-organic compound as a precursor to form a metal layer. A large quantity of organic materials such as carbon and/or oxygen as the precursor are included in the metal layer formed by the conventional ALD method. The organic materials (precursor) do not readily decompose and/or discharge by the conventional ALD method. Furthermore, when oxygen is used as a reactive gas in the conventional ALD, it is more difficult to form a pure metal layer.

### SUMMARY

Example embodiments may provide a method of forming a metal layer by using atomic layer deposition method which may prevent damage to structures below a metal layer, and the method may form a pure metal layer.

In an example embodiment, a method of forming a metal layer may include supplying a first source gas into a reaction chamber containing a substrate, purging the first source gas by supplying a first purging gas into the reaction chamber, supplying a first reactive gas containing nitrogen into the reaction chamber, and purging reaction byproducts generated by the first reactive gas by supplying a second purging gas into the reaction chamber. A plasma of the first reactive gas is formed on the substrate by applying a first RF power to the substrate when the first reactive gas is supplied to form a first metal layer.

The method may further include supplying a second source gas into the reaction chamber, purging the second source gas by supplying a third purging gas, supplying a second reactive gas into the reaction chamber, and purging reaction byproducts generated by the second reactive gas by supplying a fourth purging gas into the reaction chamber. A plasma of the second reactive gas is formed on the substrate by applying a second RF power to the substrate when the second reactive gas is applied to form a second metal layer on the first metal layer.

The method may also include supplying a third source gas into the reaction chamber, purging the third source gas by supplying a fifth purging gas, supplying a third reactive gas into the reaction chamber, and purging reaction byproducts generated by the third reactive gas by supplying a sixth purging gas into the reaction chamber. A plasma of the third reactive gas is formed on the substrate by applying a third RF power to the substrate when the third reactive gas is supplied to the substrate to form a third metal layer on the second metal layer.

### BRIEF DESCRIPTION OF THE DRAWINGS

The above and other aspects of example embodiments of the present invention will become more apparent with the detail description of example embodiments thereof with reference to the attached drawings in which:

FIG. 1A through 1D are cross-sectional views illustrating a method of forming a metal layer according to an example embodiment of the present invention;

FIG. 2 is a graph showing changes in composition of a ruthenium (Ru) layer according to forming conditions;

FIG. 3 is X-ray diffraction (XRD) analyses of four types of Ru layers formed with different forming conditions; and

FIGS. 4 and 5 are scanning electron microscopic images illustrating metal layers formed by a method of example embodiments of the present invention.

### DETAILED DESCRIPTION

Example embodiments of the present invention will now be described more fully with reference to the accompanying drawings, in which example embodiments are shown.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-section illustrations that may be schematic illustrations of idealized embodiments (and intermediate structures). As such, variations from the shapes of the illustrations as a result, for example, of manufacturing techniques and/or tolerances, are to be expected. Thus, the example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit the example embodiments.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

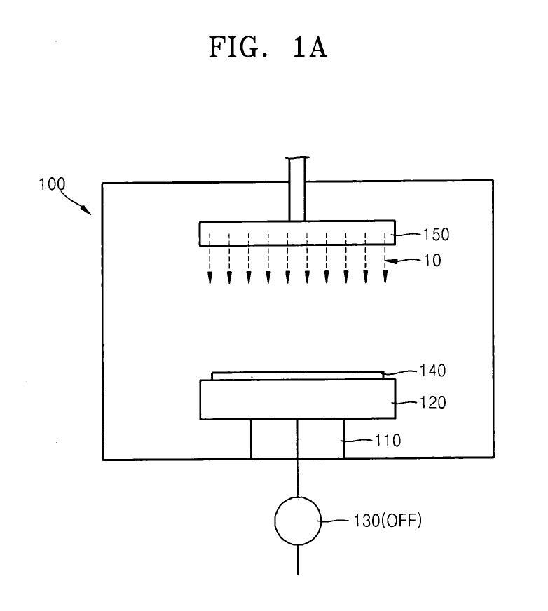

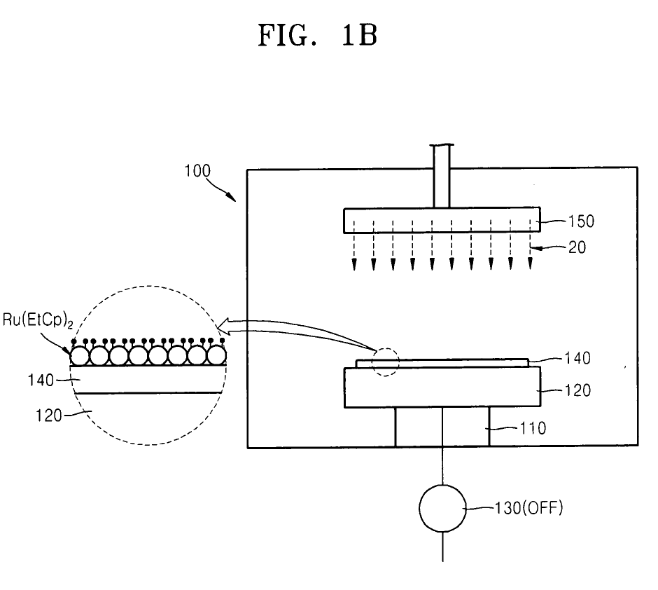

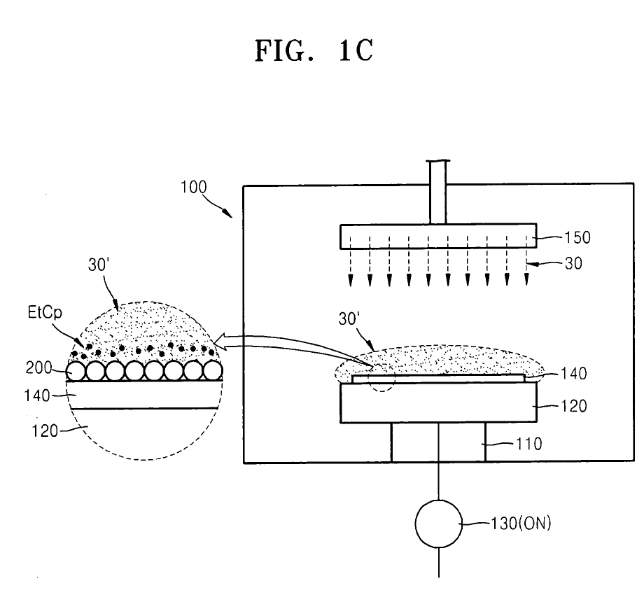

FIGS. 1A through 1D illustrate a method of forming a metal layer according to an example embodiment of the present invention. The example embodiment discloses a method of forming a ruthenium (Ru) layer using an atomic layer deposition (ALD) method.

FIG. 1A illustrates an ALD apparatus. The ALD apparatus may include a pedestal 110 and a substrate holder 120 at a lower portion of a reaction chamber 100. The substrate holder 120 may be connected to a radio frequency (RF) power generator 130. A heating apparatus (not shown) may also be provided to the reaction chamber 100. A gas injection plate, for example, a shower head 150 may be installed on a ceiling of the reaction chamber 100 at a desired distance away from the substrate holder 120. The shower head 150 may be connected to a plurality of gas supply pipes (not shown).

A substrate 140 may be loaded on the substrate holder 120. Next, a precursor 10, e.g., Ru, may be supplied through the shower head 150. The Ru may be one of Ru(EtCp)₂, Ru(OD)₃ and Ru(METHD)₂. In the current example embodiment, Ru(EtCp)₂, e.g., Ru(C₂H₅C₅H₅)₂ may be used as the precursor 10. Ru(EtCp)₂ may be supplied so that at least a single layer of Ru(EtCp)₂ covers a surface of the substrate 140. For example, an amount of time Ru(EtCp)₂ may be supplied may be approximately 0.006 seconds. The Ru(EtCp)₂ may be supplied along with a carrier gas, e.g., Ar. The amount of Ar gas supplied may be around 50 to 500 sccm, and may preferably be around 100 sccm.

Referring to FIG. 1B, a first purging gas 20 may be supplied into the reaction chamber 100 through the shower head 150. The first purging gas 20 may be an inert gas, e.g., Ar gas or N₂ gas. The amount of the first purging gas 20 supplied may be around 50 through 500 sccm, and may preferably be approximately around 100 sccm. The amount time the first purging gas 20 may be supplied is approximately 2 seconds. Then, physically adsorbed Ru(EtCp)₂ may be removed except for the single layer of Ru(EtCp)₂, which may be chemically adsorbed on an upper surface of the substrate 140.

Referring to FIG. 1C, RF power may be applied to the substrate 140 by the RF power generator 130 at the same time reactive gas 30 may be supplied into the reaction chamber 100. The reactive gas 30 may be NH₃. The amount of the reactive gas 30 supplied may be about 100 through 1000 sccm, and may preferably be about 500 sccm. The amount of time the reactive gas 30 may be supplied is about 2 seconds. The reactive gas 30 may be supplied along with an assist gas to form a plasma reaction. The assist gas may be Ar. The amount of Ar gas supplied may be about 50 to 500 sccm, and may preferably be about 100 sccm. The RF power applied to the substrate 140 may be about 100 to 1000 W, and may be about 400 through 700 W.

Nitrogen-containing plasma, e.g., NH₃ plasma 30′ may be generated around the substrate 140. The NH₃ plasma 30′ may degrade Ru(EtCp)₂ into Ru and (EtCp)₂. (EtCp)₂ may combine with NH₃ plasma 30′ and volatilize, and Ru may remain on the upper surface of the substrate 140. Therefore, a pure Ru layer 200 having an atomic layer thickness may be formed on the substrate 140. If the RF power is applied around the shower head 150 instead at near the substrate 140, NH₃ plasma 30′ may be formed separate from the substrate 140. In this case, Ru(EtCp)₂ formed on the upper surface of the substrate 140 may not degrade by NH₃ plasma 30′, and thus a pure Ru layer may not be obtained.

Referring to FIG. 1D, a second purging gas 40 may be supplied into the reaction chamber 100. The type and conditions of the second purging gas 40 may be the same as the type and the conditions of the first purging gas 20. The amount of time the second purging gas 40 may be supplied is about 1 second. Byproducts of the reaction between Ru(EtCp)₂ and NH₃ plasma 30′ may be removed by the second purging gas 40.

Supplying the precursor 10 of Ru into the reaction chamber 100; purging by supplying the first purging gas 20 into the reaction chamber 100; applying the RF power to the substrate 140 while supplying the reactive gas 30 into the reaction chamber 100; and purging by supplying the second purging gas 40 into the reaction chamber 100 may be referred to as a first through a fourth operations, respectively. In addition, the first through the fourth operations may be repetitively performed as needed. As the number of repetitions of the first through fourth operations increases, the thickness of Ru layer 200 also increases.

The method of the example embodiment of the present invention may further include treating the surface of the substrate 140 with plasma prior to the first operation. That is, the surface of the substrate 140 may be treated with plasma prior to supplying the Ru precursor 10 into the reaction chamber 100. The plasma for treating the surface of the substrate 140 may be plasma containing nitrogen, e.g., NH₃ plasma. The Ru precursor 10 may be absorbed onto the upper surface of the substrate 140 more easily when the substrate 140 is treated with the plasma.

Using the method of the example embodiment of the present invention, a pure Ru layer may be formed on the substrate 140 by effectively degrading the Ru precursor 10 without Oxygen.

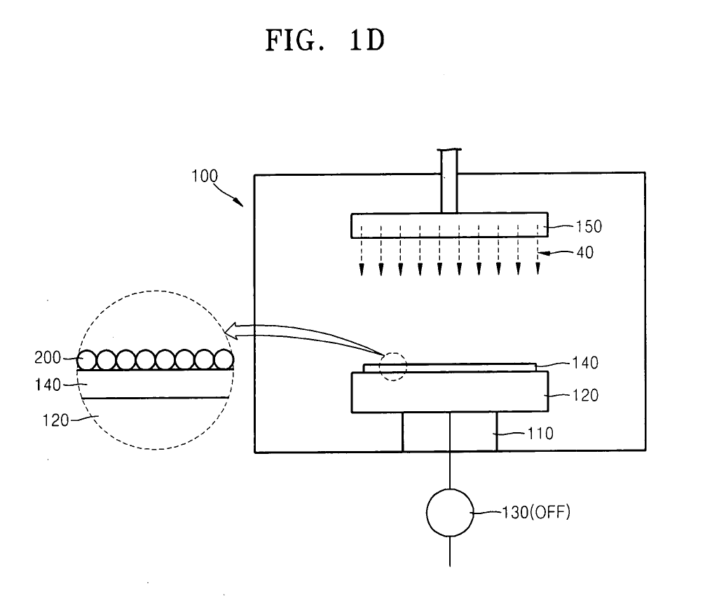

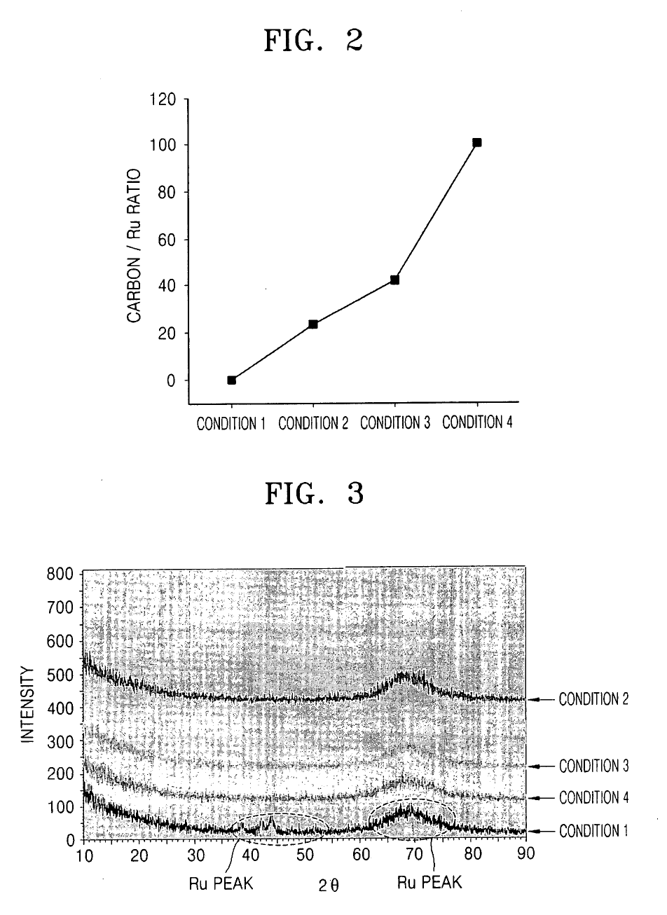

FIG. 2 is a graph showing a change in the composition of a Ru layer according to conditions (1 through 4) of the example embodiments of the present invention.

In FIG. 2, condition 1 is the forming condition applied in the method of the example embodiment of the present invention, wherein the reactive gas is NH₃+Ar. Conditions 2 through 4 are not necessarily the forming conditions of the example embodiments of the present invention, but rather the different reactive gases used for comparative purposes. The reactive gas of condition 2 is H₂, and the reactive gas of condition 3 is Ar. The difference between condition 1 and condition 4 is a reactive gas employed and RF power applied to the substrate 140 when supplying the reactive gas. In condition 4, after performing the first and the second operations, RF power is applied to the substrate 140 in conjunction with supplying Ar gas into the reaction chamber 100 so as to generate Ar plasma, and then the RF power is turned off and NH₃ gas is supplied before the fourth operation is performed.

Referring to FIG. 2, the Ru layer formed under condition 1 does not contain carbon whereas the Ru layers formed under conditions 2 through 4 contain a large quantity of carbon.

FIG. 3 illustrates results of X-ray diffraction (XRD) analyses on the Ru layers formed under conditions 1 through 4.

Referring to FIG. 3, distinct peaks of Ru crystals can be seen from an X-ray diffraction pattern of the Ru layer formed under condition 1.

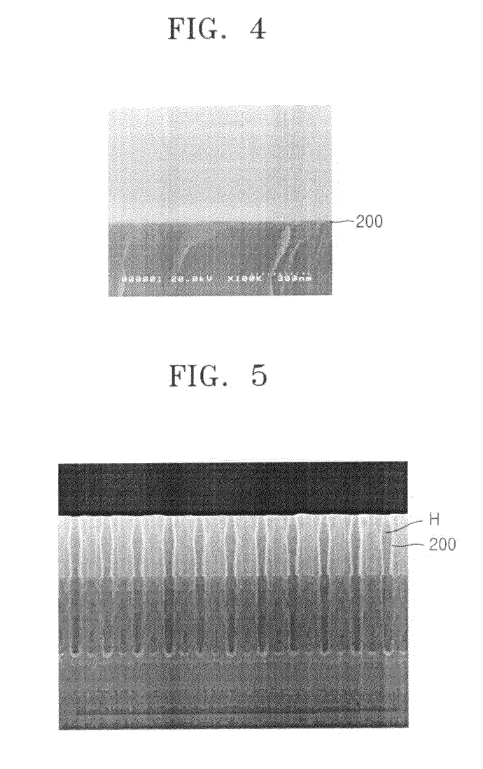

FIGS. 4 and 5 are scanning electron microscopic (SEM) images showing Ru layers formed according to example embodiments of the present invention.

FIG. 4 shows a Ru layer 200 formed on a surface, and FIG. 5 shows a Ru layer 200 formed on a surface having holes H with a large aspect ratio. Since the width and depth of the holes H in FIG. 5 are respectively 860 Å and 11700 Å, the aspect ratio of the holes H is approximately 13:1.

Other metal layers may be formed by replacing the Ru precursor 10 with precursors of other metals in the method of the example embodiment of the present invention. For example, a pure Pt layer may be obtained by using a Pt precursor, e.g., Me₃Pt(MeCp).

While forming a single metal layer was explained in the above example embodiments, the example embodiments of the present invention may also be applied to form a multi metal layer.

For example, after a first metal layer is formed by performing at least one cycle of the first through fourth operations, a fifth operation of supplying another source gas into the reaction chamber 100, a sixth operation of supplying a third purging gas into the reaction chamber 100, a seventh operation of supplying another reactive gas into the reaction chamber 100, and an eighth operation of supplying a fourth purging gas may be additionally performed. In the seventh operation, a plasma containing nitrogen may be formed around the substrate 140 by applying RF power to the substrate 140. Consequently, a second metal layer may be formed on the first metal layer. Both the first through the eighth operations or the fifth through the eighth operations may be repetitively performed. Also, the first through the fourth operations may be additionally performed after the fifth through the eighth operations are performed at least once, thereby alternately forming the first metal layer and the second metal layer. Similarly, a third metal layer may be formed on the second metal layer. Therefore, a multi metal layer including at least three different metal layers may be formed.

As described above, a plasma containing nitrogen is formed by applying RF power to the substrate 140. The plasma covers around the entire substrate 140. Accordingly, the plasma effectively degrades the precursors attached to the upper surface of the substrate 140. Thus, a pure metal layer which does not contain impurities, e.g., carbon or oxygen may be formed and oxidation of structures below the metal layer during the forming of the metal layer may be prevented.

While example embodiments have been particularly shown and described with reference to example embodiments of the present invention thereof, it will be understood by those of ordinary skill in the art that various changes in form and details may be made therein without departing from the scope of the example embodiments. For example, it would be understood by those of ordinary skill in the art that the reactive gas used in the third and the seventh operations is not limited to NH₃ gas, e.g., N₂ gas or N₂+H₂ gas may be used instead of NH₃ gas. Also, the method of the example embodiments may be applied to forming other metal layers in addition to the Ru layer and the Pt layer.

What is claimed is:

1. A method of forming a metal layer comprising:
supplying a first source gas into a reaction chamber containing a substrate;
purging the first source gas by supplying a first purging gas into the reaction chamber;
supplying a first reactive gas containing nitrogen into the reaction chamber; and
purging reaction byproducts generated by the first reactive gas by supplying a second purging gas into the reaction chamber;
wherein a plasma of the first reactive gas is formed on the substrate by applying a first RF power to the substrate when the first reactive gas is supplied to form a first metal layer.

2. The method of claim 1, wherein the metal layer is at least one of a Ru layer and a Pt layer.

3. The method of claim 1, wherein the first source gas contains at least one of a Ru precursor and a Pt precursor.

4. The method of claim 1, wherein the first source gas further contains a carrier gas.

5. The method of claim 3, wherein the first source gas further contains a carrier gas.

6. The method of claim 1, wherein the first reactive gas includes at least one of NH₃ gas and N₂ gas.

7. The method of claim 6, wherein an amount of the at least one of NH₃ gas and the N₂ gas supplied is around 100 to 1000 sccm.

8. The method of claim 3, wherein the first reactive gas further contains Ar gas.

9. The method of claim 8, wherein an amount of the Ar gas supplied is about 50 to 500 sccm.

10. The method of claim 1, wherein the first RF power is around 100 to 1000 W.

11. The method of claim 1 further comprising:
treating a surface of the substrate with plasma prior to supplying the first source gas.

12. The method of claim 11, wherein the plasma for treating the surface of the substrate contains nitrogen.

13. The method of claim 12, wherein the plasma for treating the surface of the substrate is NH₃ plasma.

14. The method of claim 1, further comprising:
repeating the steps of forming the first metal layer.

15. The method of claim 1, further comprising:
supplying a second source gas into the reaction chamber;
purging the second source gas by supplying a third purging gas;
supplying a second reactive gas into the reaction chamber; and
purging reaction byproducts generated by the second reactive gas by supplying a fourth purging gas into the reaction chamber;
wherein a plasma of the second reactive gas is formed on the substrate by applying a second RF power to the substrate when the second reactive gas is applied to form a second metal layer on the first metal layer.

16. The method of claim 15, wherein the second reactive gas includes nitrogen.

17. The method of claim 15, further comprising:
repeating all the steps of forming at least one of the first metal layer and the second metal layer.

18. The method of claim 15, further comprising:
supplying a third source gas into the reaction chamber;
purging the third source gas by supplying a fifth purging gas;
supplying a third reactive gas into the reaction chamber; and
purging reaction byproducts generated by the third reactive gas by supplying a sixth purging gas into the reaction chamber;
wherein a plasma of the third reactive gas is formed on the substrate by applying a third RF power to the substrate when the third reactive gas is supplied to the substrate to form a third metal layer on the second metal layer.

19. The method of claim 18, further comprising:
repeating all the steps of forming at least one of the first metal layer, the second metal layer, and third metal layer.

20. The method of claim 1, wherein the metal layer is formed on a substrate having a hole.
